(19) United States
(12) Patent Application Publication
(10) Pub. No.: US 2021/0099002 A1
(43) Pub. Date: Apr. 1, 2021

(54) TECHNIQUES FOR SOFTWARE IMPLEMENTED GAS-GAUGING

(71) Applicant: Apple Inc., Cupertino, CA (US)

(72) Inventors: Soham Banerjee, Boulder, CO (US); Mary-Ann Ionascu, San Francisco, CA (US)

(73) Assignee: Apple Inc., Cupertino, CA (US)

(21) Appl. No.: 16/741,631

(22) Filed: Jan. 13, 2020

Related U.S. Application Data
(60) Provisional application No. 62/907,381, filed on Sep. 27, 2019.

(51) Int. Cl. H02J 7/00; G06F 1/28

(52) U.S. Cl. CPC H02J 7/0048; G06F 1/28

(57) ABSTRACT

Embodiments of the present disclosure provide systems, methods, and computer-readable storage devices for determining a state of charge of a battery. A temperature, electrical current value, and voltage of the battery of a computing device may be obtained. A charging tier of a multi-tiered charging scheme may be identified based at least in part on the temperature and the voltage. An electrical current rate to be applied to the battery may be obtained using the temperature, the voltage of the battery, and the identified charging tier. A mapping may be obtained based at least in part on whether the battery is being charged during a constant voltage phase or a constant electrical current phase of the charging tier. A state of charge of the battery may be determined using the mapping and either the voltage or the electrical current value. The state of charge may be presented at an output device.

### CROSS REFERENCES TO RELATED APPLICATIONS

The present application claims priority from and is a nonprovisional application of U.S. Provisional Application No. 62/907,381 filed Sep. 27, 2019, the entire contents of which are herein incorporated by reference for all purposes.

### BACKGROUND

Various devices are now available that include indicators and/or interfaces for presenting the state of charge of the device's battery. Conventionally, these devices often utilize a hardware gas gauge, that can include an integrated circuit for determining the state of charge of a battery (e.g., the battery has 30% capacity remaining). These hardware gas gauges consume space, drain power resources of the device, and increase cost of the product due to chip royalties. Impedance tracking algorithms are often utilized by hardware gas gauges which require near constant monitoring of the battery such that the hardware gas gauge is almost always powered on in order to frequently check the state of the battery (e.g., every few seconds). The various features of hardware gas gauges mentioned above become particularly problematic in the context of relatively small devices that have neither the space to hold nor the spare power to support a hardware gas gauge.

### SUMMARY

Embodiments of the present disclosure can provide systems, methods, and computer-readable medium for providing a software implemented gas-gauge for determining the state of charge of a battery. In some embodiments, the battery may be charged utilizing a multi-tiered charging scheme. A “multi-tiered” charging scheme can include rules that specify that more than one electrical current rate is to be utilized to charge the battery over the course of a single charge. As a non-limiting example, a charging scheme may include rules indicating that a battery is to be charged at a relatively high current rate (e.g., 140 mA) until the battery reaches a first threshold (e.g., 3.9 V), then the electrical current rate shall drop to lower current rate (e.g., 102 mA) until the battery charge reaches a second threshold (e.g., 4.0 V), at which time the current rate shall drop again to an even lower rate (e.g., 20 mA). The example scheme can enable a device to be quickly charged to some threshold (e.g., 60% charged in 15 minutes) while utilizing a charging scheme that doesn't require high current loads for the entire charge cycle. Some battery chemistries cannot withstand high current loads for an entire charge cycle. Additionally, it is beneficial for most batteries to charge a lower charge rates at higher voltages.

In some embodiments, a computer-implemented method is disclosed. The method may comprise obtaining, by a computing device (by a gas gauge engine of a computing device) from a power management module of the computing device, a temperature, an electrical current value and a voltage of a battery of the computing device. In some embodiments, the battery may be in a charging state. The method may further comprise identifying a charging tier of a plurality of charging tiers based at least in part on a multi-tiered charging scheme, the temperature, and the voltage of the battery. The method may further comprise obtaining a mapping based at least in part on determining whether the battery is being charged during a constant voltage phase or a constant electrical current phase of the charging tier. The method may further comprise identifying a charge value corresponding to a state of charge of the battery based at least in part on the temperature and the obtained mapping, and either the voltage of the battery or the electrical current value. The method may further comprise providing the charge value for presentation.

In some embodiments, the power management module is hardware of the computing device that comprises an integrated circuit. The mapping may be one of a plurality of mappings comprising a first set of mappings to be utilized during constant voltage phases of each charging tier of the plurality of charging tiers. In some embodiments, the plurality of mappings further comprise a second set of mappings to be utilized during constant electrical current phases of each charging tier of the plurality of charging tiers.

In some embodiments, the mapping is one of a plurality of mappings, each mapping of the plurality of mappings corresponding to a temperature range and a particular charging tier of the plurality of charging tiers. The plurality of mappings may be associated with a battery type of the battery being charged. In some embodiments, the mapping (the plurality of mappings) is stored in the one or memories of the computing device, the one or more memories being non-volatile memory.

In some embodiments, the method may further comprising identifying an electrical current rate to be applied to the battery based at least in part on the temperature, the voltage of the battery, and the identified charging tier, and instructing the power management module of the computing device to apply the electrical current at the electrical current rate. In some embodiments, instructing the power management module of the computing device to apply the electrical current at the electrical current rate may comprise writing a charging value corresponding to the electrical current rate to a register of the power management module. In some embodiments, the electrical current rate decreases with each successive tier according to the multi-tier charging scheme. In some embodiments, the multi-tiered charging scheme specifies that the electrical current rate applied to the battery differs between at least two charging tiers.

In some embodiments, the temperature is obtained from a thermal sensor of the computing device. In some cases, the temperature, the electrical current value, and the voltage of the battery may be obtained from the power management module by a software module of the computing device. For example, the software module can be firmware of the computing device.

In some embodiments, the method may further comprise modifying the charge value based at least in part on one or more smoothing techniques. In some embodiments, the voltage is utilized to identify the charge value corresponding to the state of charge of the battery when the battery is being charged during a constant electrical current phase of the charging tier, and the electrical current rate is utilized to identify the charge value corresponding to the state of charge of the battery when the battery is being charged during the constant voltage phase of the charging tier.

In some embodiments, the method may further comprise collecting historical charging data including an age of the battery, a number of cycles corresponding to charges of the battery performed, historical electrical current rates, and an average voltage of the battery over a period of time that corresponds to the age of the battery. In some examples, the method may comprise adjusting the multi-tier charging scheme based at least in part on the historical charging data collected over time.

In some embodiments, the method further comprises filtering the temperature and voltage utilizing an out of bounds check to remove outlier temperatures and voltages.

Another embodiment discloses an apparatus comprising a battery, a memory comprising computer-executable instructions, and one or more processors in communication with the memory and configured to access the memory and execute the computer-executable instructions to perform any of the methods described herein.

Another embodiment discloses one or more computer-readable storage devices comprising computer-executable instructions that, when executed by one or more processors, cause the one or more processors to perform any of the methods described herein.

The following detailed description together with the accompanying drawings will provide a better understanding of the nature and advantages of the present disclosure.

### BRIEF DESCRIPTION OF THE DRAWINGS

FIG. 1 is a simplified block diagram illustrating an example flow for determining the state of charge of a battery utilizing a software gas gauge (e.g., a gas gauge engine), in accordance with at least one embodiment.

FIG. 2 is a graph illustrating a multi-tiered charging scheme, in accordance with at least one embodiment.

FIG. 3 is a schematic diagram of an example computer architecture for a device executing the gas gauge engine, the gas gauge engine including a plurality of modules that may perform functions in accordance with at least one embodiment.

FIG. 4 is a simplified block diagram illustrating an example flow for determining a state of charge of a battery, in accordance with at least one embodiment.

FIG. 5 is a schematic diagram illustrating an example table associated with a charging scheme that may be utilized to identify an electric current rate to be applied to a battery during a charging state, in accordance with at least one embodiment.

FIG. 6 is a schematic diagram illustrating example tables associated with constant voltage phases of a multi-tiered charging scheme, in accordance with at least one embodiment.

FIG. 7 is a schematic diagram illustrating example tables associated with constant current phases of a multi-tiered charging scheme, in accordance with at least one embodiment.

FIG. 8 is a flow diagram to illustrate an example method for determining a state of charge of a battery, in accordance with at least one embodiment.

### DETAILED DESCRIPTION

Certain embodiments of the present disclosure can provide systems, methods, and computer-readable medium for providing a software implemented gas-gauge for determining the state of charge of a battery. In various embodiments, the battery may be charged utilizing a multi-tiered charging scheme. A “multi-tiered” charging scheme can include rules that specify that more than one electrical current rate is to be utilized to charge the battery over the course of a single charge. As a non-limiting example, a charging scheme may include rules indicating that a battery is to be charged at a relatively high current rate (e.g., 140 milliamps (mA)) until the battery reaches a first threshold (e.g., 3.9 V (3900 millivolts (mV))), then the electrical current rate shall drop to lower current rate (e.g., 102 mA) until the battery charge reaches a second threshold (e.g., 4.0 V), at which time the current rate shall drop again to an even lower rate (e.g., 20 mA). The example scheme can enable a device to be quickly charged to some threshold (e.g., 60% charged in 15 minutes) while reducing the overall heat experienced by the device during charging. The reduced heat is achieved by subsequently reducing the current rate such that the device is not charged for the entire charge at a high heat producing current rate (e.g., 140 mA).

In some embodiments, a device may be configured to execute a charging scheme having multiple tiers of charging. As a non-limiting example, the device can be configured to execute a charging scheme having three tiers of charging, although any suitable number of tiers may be utilized. The device may include a power management module such as an integrated circuit. In some embodiments, the power management module may be configured to manage charging of a battery of the device. By way of example, the device could be one of a pair of Bluetooth® wireless headphones having a rechargeable battery and a power management module that manages the charging of the battery (e.g., managing a rate of electrical current provided to the battery). The battery may be of any suitable storage capacity or form factor.

Firmware of the device (or another software module) may include code that, when executed, provide a gas gauge engine configured to, among other things, identify a rate of electrical current to be provided to the battery and a state of charge of the battery. In some embodiments, a state of charge may refer to an amount of charge currently stored on the battery. The state of charge may be expressed in any suitable units such as volts or the state of charge may be expressed in a percentage of a total capacity of the battery (e.g., 30% charge remaining), and/or the state of charge may be expressed as an estimation of remaining run time (e.g., 55 minutes).

The gas gauge engine may receive a current voltage (e.g., a voltage measured at a particular time) and a current temperature (e.g., a temperature measured at a particular time) of the battery. In some embodiments, the current voltage may be provided by a power management module (e.g., an integrated circuit of the device) and the current temperature may be provided by a sensor of the device (e.g., a thermal sensor configured to measure the temperature of the battery). Using the current voltage and the current temperature, the gas gauge engine may consult one or more predefined and previously stored tables that defines a rate of electrical current to be applied to the battery in accordance with the temperature and current voltage. The table may define multiple sets of data, each set corresponding to a different charging tier of the multi-tiered charging scheme. Each set of data corresponding with a charging tier may include multiple electrical current rates each corresponding to a different temperature range. The gas gauge engine may identify a rate of electrical current from the table utilizing a combination of the temperature and current voltage of the battery. In some embodiments, the gas gauge engine may instruct the power management module to apply electrical current at a rate corresponding to the electrical current rate identified. In some embodiments, instructing the power management module can include writing a charging value corresponding to the electrical current rate to a register of the power management module.

During the process for identifying the electrical current rate, the gas gauge engine may determine which charging tier corresponds to the current charging. Each charging tier may include a phase associated with constant voltage and a phase associated with constant current. Given the current voltage and/or current electrical current of the battery, the gas gauge engine may identify whether the battery is being charged during a constant voltage phase or a constant current phase.

To identify a state of charge of the battery the gas gauge engine may utilize the temperature, current voltage, current charging tier, and a determination that the charging is currently occurring during a constant voltage phase or a constant current phase of the current charging tier. In some embodiments, the gas gauge engine may be configured to access one or more tables stored in non-volatile memory of the device. Each table may correspond to a particular charging tier and either a constant voltage phase or a constant current phase. By way of example, for a three-tiered multi-tiered charging scheme, three tables may be stored each being associated with a constant voltage phase of each charging tier. Likewise, three more tables may be stored, each being associated with a constant current phase of each charging tier. In some embodiments, these six tables may correspond with a particular temperature range (e.g., 0°-4° Celsius (C)). Multiple temperature ranges may be utilized, each range having six tables for a three-tiered charging scheme. Thus, if five temperature ranges are utilized, the device may store 30 total predefined tables. It should be appreciated that any suitable number of charging tiers may be utilized and any suitable number of temperature ranges.

Given a determination that the device is charging in a constant voltage phase of a first tier and the temperature is 21° C., the gas gauge engine may retrieve a table corresponding to the constant voltage phase of the first tier and a temperature of 21° C. The table may include any suitable number of electrical current values. Each of the electrical current values may be utilized as a lookup to obtain a current state of charge value. For example, a value of 133 mA may be mapped to a table associated with constant voltage and a first charging tier. The value 133 mA may be mapped with the table to a particular charge amount e.g., a current charge of 3550 mV out of 4200 mV or approximately 19% charged). In some embodiments, the particular charge amount (e.g., 3550 mV) may correspond to a particular percentage (e.g., 19%) of possible charge of the device. In some embodiments, a number of smoothing techniques may be utilized with the identified charge amount to ensure a good user experience when the state of charge of the battery is presented. It should be appreciated that in some embodiments, the state of charge of the battery may be provided on the device itself and/or via another device (e.g., a smartphone) associated with and/or paired with the device (e.g., a set of Bluetooth wireless headphones).

The procedures discussed herein may decrease enable devices (e.g., small devices such as Bluetooth headphones and the like) to provide accurate state of charge estimations without requiring a hardware gas gauge that might take up too much space and/or utilize too much power to enable efficient power consumption. Utilizing the techniques discussed herein, the estimated state of charge of the device may be more accurate than would be case if a hardware gas gauge was utilized. This may result from the fact that the gas gauge engine discussed herein has knowledge of the charging scheme utilized while a hardware gas gauge would not be. This may be particularly useful with multi-tiered charging schemes as a hardware gas gauge would have even greater difficulty due to the changing current rates across tiers.

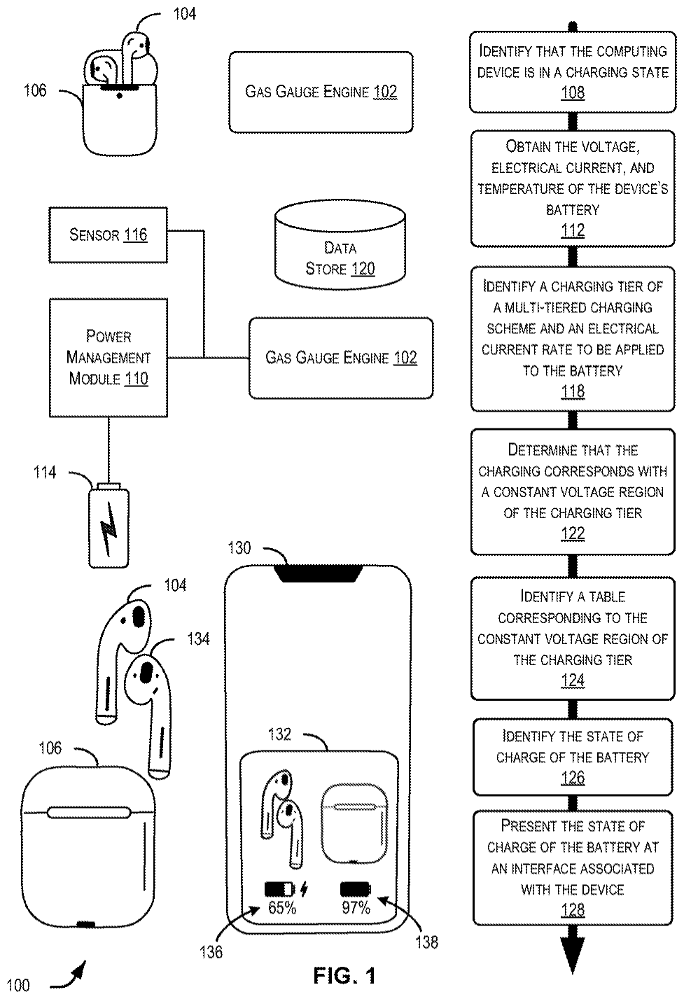

FIG. 1 is a simplified block diagram illustrating an example flow 100 for determining the state of charge of a battery utilizing a software gas gauge (e.g., a gas gauge engine 102), in accordance with at least one embodiment. In some embodiments, the gas gauge engine 102 may execute as part of a computing device. For example, computing devices such as wireless headphone 104 and/or charging device 106 may each execute an instance of the gas gauge engine 102.

The flow 100 may begin at block 108, where it may be identified that the computing device (e.g., wireless headphones 104) is in a charging state. As a non-limiting example, charging device 106 may be configured to charge wireless headphone 104 when the wireless headphone 104 is inserted into a charging dock of the charging device 106 as depicted in FIG. 1. A module of the wireless headphone 104 (e.g., a power management module 110, the gas gauge engine 102) may be configured to identify that the wireless headphone 104 is operating in a charging state (e.g., connected to the charging device 106). While wireless headphones are utilized in the example depicted in FIG. 1, it should be appreciated that the disclosed techniques could similarly be applied to devices other than wireless headphones.

At block 112, the power management module 110 of the wireless headphone 104 may obtain the voltage of the battery 114 (the battery of wireless headphone 104), and electrical current, and a current temperature of the battery 114. In some embodiments, the power management module 110 may include an integrated circuit configured to control the charging and/or discharging of the battery 114. In some embodiments, the power management module 110 may include sensor 116 (e.g., a thermal sensor) or the sensor 116 may be external to the power management module 110 and located elsewhere on the wireless headphone 104. The sensor 116 may be configured to measure the temperature, while the power management module 110 may be configured to determine the electrical current and voltage at the battery 114. The power management module 110 may provide (e.g., via an application programming interface or otherwise) the voltage, the electrical current, and the temperature of the battery 114 to the gas gauge engine 102 to stimulate the functionality provided by the gas gauge engine 102.

At block 118, a charging tier of a multi-tiered charging scheme and an electrical current rate to be applied to the battery 114 may be identified by the gas gauge engine 102. A multi-tiered charging scheme may define any suitable number (e.g., two or more) charging tiers. Each charging tier may be associated with a corresponding electrical current rate to be applied to a battery during a time period corresponding to that charging tier. In some embodiments, the electrical current rates may decrease to some degree with each consecutive charging tier. Thus, a first charging tier may be associated with an electrical current rate that is greater than that of a second charging tier, which may be associated with an electrical current rate that is greater than that of a third charging tier, and so on. In some embodiments, the gas gauge engine 102 may store a table (e.g., a mapping) that identifies a charging tier and an electrical current rate based at least in part on an input voltage and an input temperature. In some embodiments, the table may be stored at the wireless headphone 104 in data store 120. Data store 1120 may be non-volatile memory that may persist even if the wireless headphone 104 is turned off. The data store 120 may be accessible to the gas gauge engine 102.

Using the temperature and voltage received from the power management module, the gas gauge engine 102 may identify the charging tier and the corresponding electrical current rate (also referred to as a charge rate) to be applied to the battery 114. By way of example, if the voltage of battery 114 is relatively low, a first charging tier (e.g., a first charging tier of three charging tiers) may be identified, the first charging tier being associated with the greatest electrical current rate. It should be appreciated that the table may define electrical current rates based at least in part on different temperature ranges. In some examples, the electrical current rate may not decrease between at least one pair of consecutive charging tiers. For example, in some temperature ranges, each charging tier charging tier may maintain a relatively low electrical current rate.

At block 122, the gas gauge engine 102 may determine (e.g., utilizing a multi-tiered charging scheme, another table, or the like stored in data store 120) that charging is occurring during a constant voltage phase of the charging tier. The electrical current and/or the voltage received at 112 may be utilized to identify whether charging is occurring during a constant voltage phase or a constant electrical current phase of the charging tier. As a non-limiting example, the gas gauge engine 102 may identify a table, and/or graph, or any suitable container that provides voltages and electrical current rates corresponding to a constant voltage phase and/or constant electrical current rate phase for each charging tier.

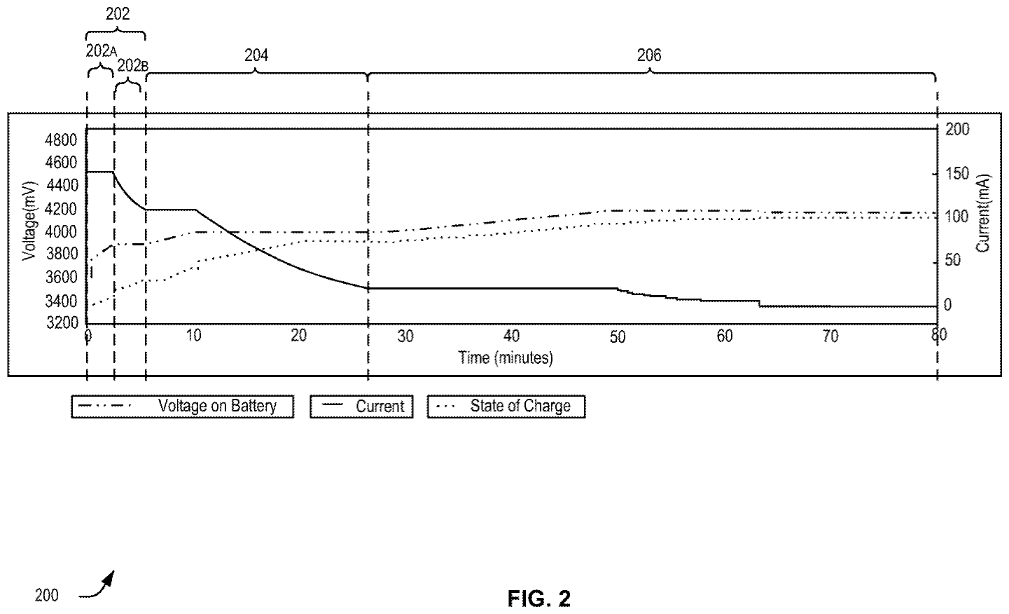

By way of example, FIG. 2 is a graph 200 illustrating an exemplary multi-tiered charging scheme, in accordance with at least one embodiment. The graph 200 (or a mapping or table corresponding to the graph 200) may be stored at a device (e.g., in the data store 120 of the wireless headphone 104 of FIG. 1) to be utilized to identify whether the charging is occurring in a constant voltage phase or a constant electrical current rate phase of a charging tier.

In FIG. 2, the graph 200 corresponds to a three-tiered charging scheme, although any suitable number of two or more charging tiers could likewise be utilized. The graph 200 depicts the voltage, electrical current, and state of charge during each of the charging tiers 202, 204, and 206. Each charging tier includes a constant electrical current rate phase and a constant voltage phase. For example, charging tier 202 includes a constant electrical current rate phase 202A during which the electrical current rate remains constant and the voltage is changing, and a constant voltage phase 202B during which the voltage is constant and the electrical current rate is changing. Thus, utilizing the voltage and the electrical current rate, a particular phase (e.g., constant voltage phase 202B) may be identified.

In some embodiments, there are three phases in charging: a pre-charge phase, a constant current phase, a constant voltage phase. In some embodiments, a battery may not undergo a pre-charge phase unless the battery is deeply discharged. In a pre-charge phase, a battery may be deeply discharged (e.g., the voltage is below a threshold voltage). Since the battery is charging in this phase, the charge value corresponding to the state of the battery may be set to 1%. The batter may be charged at a low charge rate to prevent causing stress until the voltage reaches the threshold voltage. After the battery reaches the threshold voltage, the battery may enter a constant current phase of charging. A battery undergoes a constant current phase when the terminal voltage of the battery is more than the threshold voltage and less the voltage applied by a charging device (e.g., the charging device 106 of FIG. 1). Once a predefined taper voltage for a charging tier is reached the battery voltage may remain constant and the electrical current rate may start decreasing. The phase where the current is decreasing and the voltage attains the taper voltage may be referred to as a constant voltage phase.

It should be appreciated that the graph 200 depicts a multi-tiered charging scheme that provides a number of advantages. First, because the electrical current rate applied to the battery drops with each consecutive charging tier 202, 204, and 206, the life of the battery may be extended due to utilizing lower electrical current rates at higher voltages. Additionally, by utilizing a relatively high electrical current rate during a first charging tier (e.g., charging tier 202), the battery may be charged to approximately 60% capacity in a relatively short time (e.g., approximately 15 minutes in this use case). This may improve the user's experience with charging the device as the charging may be more rapid in the beginning to enable the user to quickly charge the device to at least 60% capacity.

Returning to FIG. 1, at block 122, the graph 200 of FIG. 2 (or a corresponding table) may be utilized by the gas gauge engine 102 to identify that the charging currently underway corresponds with a constant voltage phase of the charging tier (e.g., the first charging tier). In other embodiments, the gas gauge engine 102 may identify that the charging currently underway corresponds with a constant electrical current rate phase of the first charging tier.

At block 124, a table (also referred to as a “mapping”) corresponding to the constant voltage phase of the charging tier (e.g., the first charging tier) may be identified by the gas gauge engine 102. The table may be one of many tables. By way of example, any suitable number of tables may be stored at the data store 120. In some embodiments, a first set of those tables may correspond to constant voltage phases and a second set of those tables may correspond to constant electrical current rate phases. Any given table may be associated with a constant voltage or electrical current rate phase, a particular charging tier, and a temperature range. Thus, for a three-tiered charging scheme, there may be 15 constant voltage tables, a set of five for each of the three charging tiers, each of the set of five corresponding to a five different temperature ranges. Five temperature ranges is used as an illustrative example only, any suitable number of temperature ranges may be utilized. Similarly, there may be 15 constant electrical current rate tables, a set of five for each of the three charging tiers, each of the set of five corresponding to one of the five temperature ranges.

If the charging of the device is occurring during a constant voltage phase of the charging tier as determined at block 122, the gas gauge engine 102 may obtain the table corresponding to the constant voltage phase of the first charging tier of the multi-tiered charging scheme. The table may provide a mapping between an electrical current rate and a charge value corresponding to a state of charge of the battery.

At block 126, a state of charge of the battery may be identified by the gas gauge engine 102. For example, by utilizing the table and the electrical current of the battery 114 as received at 112, a charge value may be identified for the battery 114. In some embodiments, the charge value may indicate an amount of charge with respect to the capacity of the battery 114 at that time. In some embodiments, the charge value may be a percentage (e.g., 12%, 15%, etc.) or the charge value may differ in format (e.g., such as being expressed in volts or millivolts, etc.) but may be converted by the gas gauge engine 102 to a percentage (or any suitable format) indicating the amount of charge with respect to the capacity of the battery 114.

At block 128, the state of charge of the battery 114 may be presented at an interface associated with the device. In some embodiments, the state of charge of the battery 114 may be presented at an interface of the device itself (e.g., utilizing a light or other indicator of the wireless headphone 104). In some embodiments, the state of charge of the battery 114 may additionally or alternatively be presented at an output device different from the device being charged. For example, user device 130 may correspond to a device that is paired or otherwise in communication with the wireless headphone 104. Thus, in some embodiments, the user device 130 (e.g., a smartphone) may present interface 132 with which the state of charge of the wireless headphone 104 may be presented. In some embodiments, the state of charge of wireless headphone 104 may be averaged with the state of charge of wireless headphone 134 (also executing an instance of the gas gauge engine 102) to produce charge value 136. As another example, the lowest charge value of wireless headphone 104 or 134 may be utilized as charge value 136. Any suitable process for calculating the charge value 136 from the charge value of wireless headphones 104 and/or 136 may be utilized. Similarly, the charge value 138 corresponding to the charging device 106 (e.g., a chargeable mobile battery charger that executes an instance of the gas gauge engine 102) may be displayed via the interface 132 according to some embodiments.

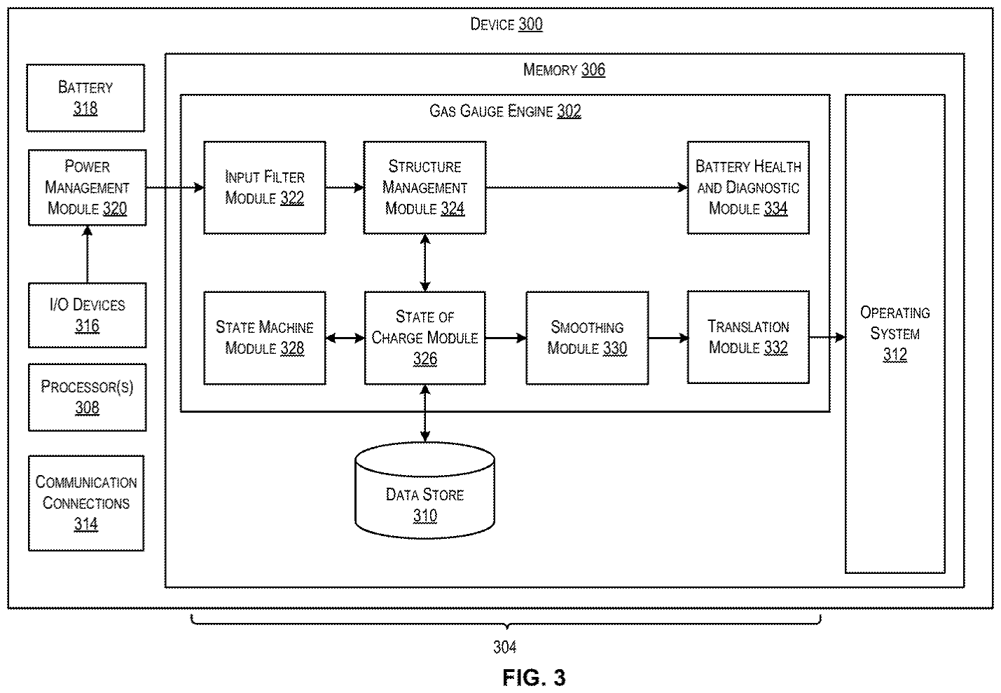

FIG. 3 is a schematic diagram of an example computer architecture for a device 300 executing the gas gauge engine 302, the gas gauge engine 302 including a plurality of components (e.g., components 304) that may perform functions in accordance with at least one embodiment. In some embodiments, the device 300 may be an example of the wireless headphone 104 and/or wireless headphone 134 of FIG. 1, and/or the charging device 106 of FIG. 1. The gas gauge engine 302 may be an example of the gas gauge engine 102 of FIG. 1.

In one illustrative configuration, the device 300 may include at least one memory 306 and one or more processing units (e.g., processor(s)) 308). The processor(s) 308 may be implemented as appropriate in hardware, computer-executable instructions, firmware, or combinations thereof. Computer-executable instruction or firmware implementations of the processor(s) 308 may include computer-executable or machine-executable instructions written in any suitable programming language to perform the various functions described.

The memory 306 may store program instructions that are loadable and executable on the processor(s) 308, as well as data generated during the execution of these programs. Depending on the configuration and type of user computing device, the memory 306 may be volatile (such as random access memory (RAM)) and/or non-volatile (such as read-only memory (ROM), flash memory, etc.). In some embodiments, the data store 310 may reside in non-volatile memory. The device 300 may also include additional removable storage and/or non-removable storage including, but not limited to, magnetic storage, optical disks, and/or tape storage. The disk drives and their associated computer-readable media may provide non-volatile storage of computer-readable instructions, data structures, program modules, and other data for the computing devices. In some implementations, the memory 306 may include multiple different types of memory, such as static random access memory (SRAM), dynamic random access memory (DRAM), or ROM.

The memory 306, both removable and non-removable, is an example of computer-readable storage media. For example, computer-readable storage media may include volatile or non-volatile, removable or non-removable media implemented in any method or technology for storage of information such as computer-readable instructions, data structures, program modules, or other data. Additional types of computer storage media that may be present in the device 300 may include, but are not limited to, PRAM, SRAM, DRAM, RAM, ROM, EEPROM, flash memory or other memory technology, CD-ROM, DVD or other optical storage, magnetic cassettes, magnetic tape, magnetic disk storage or other magnetic storage devices, or any other medium which can be used to store the desired information and which can be accessed by the processor(s) 308. Combinations of any of the above should also be included within the scope of computer-readable media. Alternatively, computer-readable communication media may include computer-readable instructions, program modules, or other data transmitted within a data signal, such as a carrier wave, or other transmission. However, as used herein, computer-readable storage media does not include computer-readable communication media.

Turning to the contents of the memory 306 in more detail, the memory 306 may include an operating system 312, one or more data stores (e.g., data store 310, and one or more application programs, modules, or services for implementing the features of the gas gauge engine 302 disclosed herein, such as the components 304.

The device 300 may also contain communications connection(s) 314 that allow the device 300 to communicate with a stored database, another computing device or server (e.g., the user device 130 of FIG. 1), user terminals and/or other devices on any suitable communications network. The device 300 may also include I/O device(s) 316, such as a keyboard, a mouse, a pen, a voice input device (e.g., a microphone), a touch input device, a display, one or more speakers, a printer, etc. In some embodiments, the I/O device(s) 316 may include a thermal sensor or any suitable device configured to ascertain a temperature of the battery 318. The device 300 may be configured to operate on power provided by the battery 318. The battery 318 may be any suitable capacity and/or type of battery including but not limited to lithium-ion batteries, nickel cadmium batteries, nickel-metal hydride batteries, and/or lead-acid batteries.

The power management module 320 may be an example of the power management module 110 of FIG. 1. In some embodiments, the power management module may be an integrated circuit configured to manage charging of the battery. The power management module 320 may be communicatively connected to the gas gauge engine 302 via any suitable bus, conductive track, or the like. In some embodiments, the power management module 320 may include a thermal sensor or a thermal sensor configured to measure the temperature of the battery 318 may be included in I/O device(s) 316 and may be communicatively connected to the power management module 320. In some examples, the power management module 320 may determine a voltage of the battery 318, and an electrical current being applied to the battery (if current is being applied to the battery 318, and may receive a temperature from a thermal sensor (e.g., a sensor of the I/O device 316). The power management module 320 may be configured to provide values corresponding to the voltage, the electrical current, and the temperature to any suitable component of the gas gauge engine 302 (e.g., the input filter module 322).

The gas gauge engine 302 may include a plurality of modules (e.g., components 304) that may perform functions of the gas gauge engine 302 discussed herein. The components 304 may be software modules embodied on a computer readable medium and processed by the processor(s) 308.

In the embodiment depicted in FIG. 3, the data store 310 is shown, although data can be maintained, derived, or otherwise accessed from various data stores, either remote or local to the gas gauge engine 302, to achieve the functions described herein. In at least one embodiment, the data stores described herein may be physically located on the device 300 or alternatively, any suitable combination of the data stores may be operate as part of a remote computing system (e.g., a server) with which the device 300 can communicate (e.g., over a wireless and/or wired communications network such as the Internet or a cellular network). The device 300, includes various modules such as an input filter module 322, a structure management module 324, a state of charge module 326, a state machine module 328, a smoothing module 330, a translation module 332, and a battery health and diagnostics module 334. Some functions of the components 304 are described below. However, for the benefit of the reader, a brief, non-limiting description of each of the modules is provided in the following paragraphs. In some embodiments, the gas gauge engine 302 may be implemented in firmware of the device 300.

In at least one embodiment, the device 300 includes the input filter module 322. The input filter module 322 may be responsible for filtering inputs to the gas gauge engine 302. In some examples, the input filter module 322 may be configured to receive input (e.g., voltage, electrical current, and temperature). In some embodiments, the inputs may be digital values of voltage, electrical current, and temperature or the inputs may be received in any suitable format and converted by the input filter module 322. In some embodiments, the input filter module 322 may receive these inputs from the power management module 320. The input filter module 322 may be responsible for executing one or more out of bounds checks and removing noise from the input. In some embodiments, a moving average filter may be implemented to smooth the stream of inputs. In some embodiments, a sample size of a buffer and a sample rate of the filter may be chosen after performing a mean, standard deviation analysis on received raw data. An out of bounds check may allow raw values of voltage, current, and temperature that fall within a ranges defined by maximum and minimum values corresponding to voltage, current, and temperature. The out of bounds check may reject extraneous values. In some embodiments, the input filter module 322 may be configured to identify when the temperature input exceeds a threshold limit for over a threshold time period. When these conditions are detected, the input filter module 322 may determine that the device 300 is unsafe to function and may instruct any suitable component of the device 300 to shut down the device 300. In some embodiments, the input filter module 322 may be configured to pass the raw values and/or converted values to the structure management module 324 after filtering has concluded.

The structure management module 324 may be responsible for maintaining a data structure used to store the filtered input values, among other data. This structure may be utilized by any suitable module of the gas gauge engine 302 to perform any suitable function and/or operation. In some embodiments, the data structure may be static and updated with any suitable parameters that can be utilized by the components 304. The data structure may be stored by the structure management module 324 in data store 310 or at any suitable storage location. The structure management module 324 may be configured to provide the data structure to any suitable component of the gas gauge engine 302 (e.g., the state of charge module 326, the battery health and diagnostic module 334).

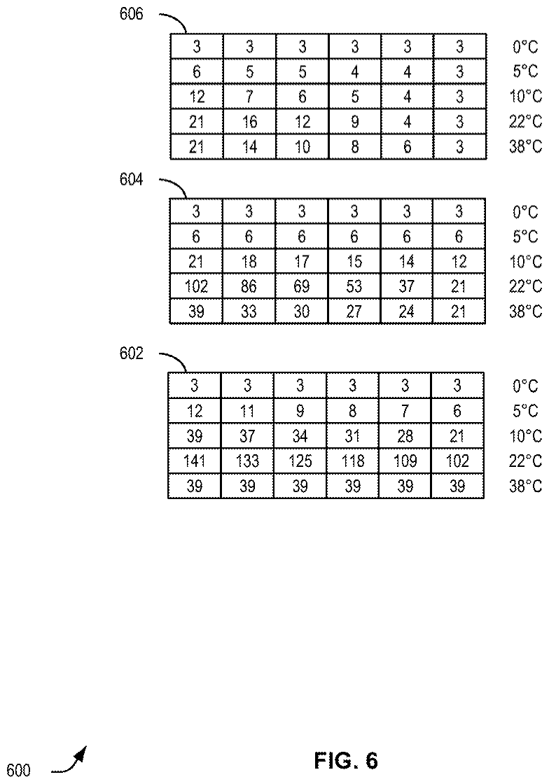

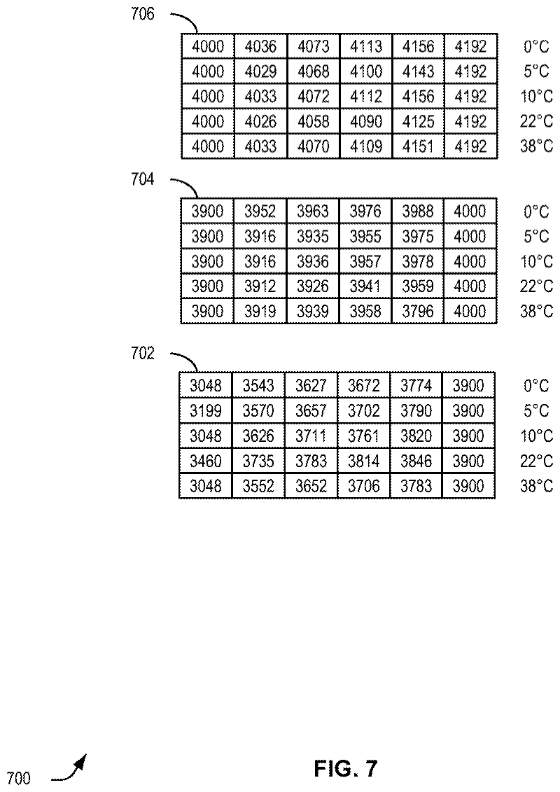

The state of charge module 326 may be configured to look up and interpolate to calculate a charge value (e.g., a battery level) based at least in part on tables such as the tables discussed above in FIG. 1 and depicted in FIGS. 6 and 7. In some embodiments, the tables depicted in FIGS. 6 and 7 correspond to a charging state during which the battery 318 may be charging. It should be appreciated that, in some embodiments, the tables may be associated with a particular type of battery (e.g., the tables may be specific to that battery type). The state of charge module 326 may be configured to execute a gas gauge algorithm that may be utilized to determine when charging is in a constant voltage or constant electrical current rate phase of a charging tier (e.g., a charging tier of a multi-tiered charging scheme). The state of charge module 326 may be configured to request a current state from the state machine module 328.

In some embodiments, the state machine module 328 may be configured to mimic the states of the battery 318 utilizing a state machine. The state machine provided by the state machine module 328 may include three states: charged, charging, and discharging, although any suitable number of states may be utilized. In some embodiments, battery 318 can have only two states, charging and discharging. If a “charged” state is utilized, the charged state may be utilized to mimic the top off behavior of the battery 318. In some embodiments, Li-ion batteries may need to be topped off after they are fully charged to prevent stress. A charged state may be utilized when the charging current reaches the value of predefined termination current value. When the termination current value is reached, the state machine module 328 (or another suitable component of the gas gauge engine 302)) may be configured to instruct the power management module 320 to disable the charging which may cause the terminal voltage of the battery 318 to decrease. Once the voltage is below a limit, the state machine may be configured to change state to “discharging.” When in a charged state of the state machine, the state machine module 328 may set the battery level to 100%. This state may be used for battery top off purposes. If current is determined to be less than 0, the state machine may transition to a discharging state. If current is determined to be greater than 0, the state machine may be in a charging state.

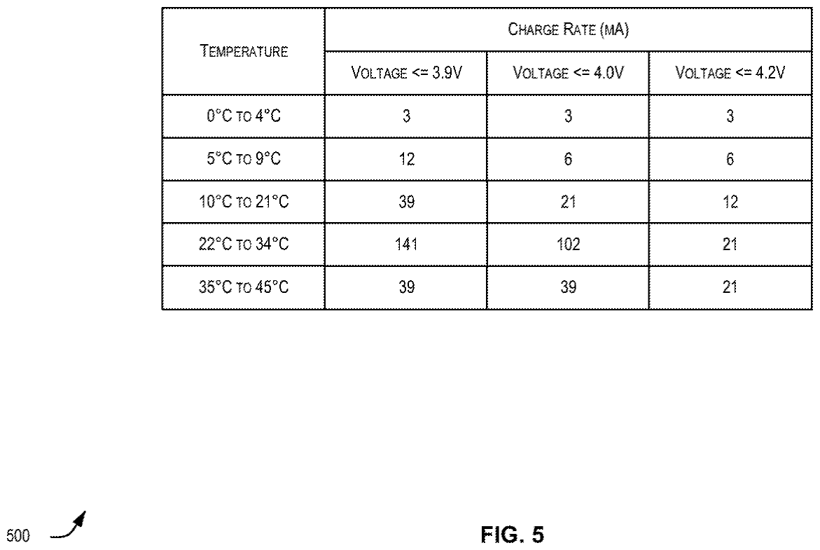

In some embodiments, if the state returned by the state machine module 328 indicates a charging state, the state of charge module 326 may be configured to identify an electrical current rate to be applied to the battery 318. For example, a table stored in the data store 310 may be obtained. The table (also referred to as a mapping) may map inputs such as voltage and temperature to a charging tier and an electrical current rate to be applied for that charging tier. The table may be multi-dimensional. An example of the table is depicted in FIG. 5. Utilizing the voltage and temperature provided in the data structure, the state of charge module 326 may determine the charging tier and the electrical current rate to be applied for that charging tier. In some embodiments, the state of charge module 326 may be configured to instruct power management module 320 to apply electrical current at the rate identified. In some embodiments, the identified charging tier and/or the identified electrical current rate to be applied for that charging tier may be stored in the data structure maintained by the structure management module 324.

In some embodiments, the state of charge module 326 may be configured to identify whether charging is occurring during a constant voltage phase or a constant electrical current phase of the charging tier (e.g., utilizing the graph 200 of FIG. 2 or any suitable algorithm for identifying the occurrence of a constant voltage or constant electrical current phase). For example, the state of charge module 326 may utilize the voltage and/or the electrical current stored in the data structure provided by the structure management module 324 to identify whether charging is currently in a constant voltage phase or a constant electrical phase of a particular charging tier. In some embodiments, the state of charge module 326 may be configured to retrieve a table corresponding to the charging tier, the temperature, and the constant voltage/electrical current phase. By way of example, in the constant voltage phase, a table corresponding to the constant voltage phase, the temperature provided in the data structure, and the charging tier may be retrieved from data store 310. This table (also referred to as a mapping) may be multidimensional and may identify a charge value (e.g., a percentage of charge or a value corresponding to a percentage of charge of the batter). Examples of such tables are depicted in FIG. 6. Using the electrical current (e.g., as provided within the data structure provided by the structure management module 324) as input/a look up value, the state of charge module 326 may retrieve a charge value corresponding to a state of charge of the battery. If the electrical current value falls between two points, a linear interpolation technique may be utilized to estimate the charge level. In some embodiments, the state of charge module 326 may convert the charge value to a percentage value indicating a percentage of charge of the battery 318 with respect to a total capacity of the battery 318, although any suitable conversion may be utilized to identify a value that indicates a state of charge of the battery 318.

In some embodiments, the state of charge module 326 may provide the charge value (and/or a raw version of the charge value) to the smoothing module 330. The smoothing module 330 may be configured to cause the charge values provided over time correspond to real state of charge behavior. By way of example, raw state of charge values (e.g., the charge values provided by the state of charge module 326 over time) may vary in a manner that doesn't match an expected charging behavior (e.g., where the charge level increases over time without decreasing during the charging state). For example, the raw state of charge values may fluctuate rather wildly. The smoothing module 330 may be configured to alleviate these variations. For example, the smoothing module 330 may be configured to cause the state of charge value to only increment or decrement by 1% every x seconds and to be bounded between 0 and 100%. If x were to be made constant, an error may accumulate between the state of charge presented (e.g., at the device 300 or another device communicatively connected with the device 300) and the raw state of charge value. The accumulated error could rise due to the non-linear behavior of voltage versus the state of charge value in the lower 20% capacity of the battery 318 (see graph 200 of FIG. 2). Thus, in some embodiments, x may be determined utilizing a non-linear function of the raw state of charge value. In some embodiments, the smoothing module 330 may update a timestamp every time the state of charge value is incremented or decremented (e.g., at a user interface). The timestamp may be utilized by the smoothing module 330 to ensure that updates to the state of charge value do not occur unless it has been x seconds since the last update. The variable x may be predefined or user defined.

In some embodiments, the smoothing module 330 may be configured to perform additional smoothing operations. For example, since the state of charge may be calculated based on voltage, there might be scenarios where the battery voltage is reported as being less than a minimum threshold and the state of charge may be presented is stuck at a value greater than 1%. This may occur when the charge value falls in the 0%-20% of battery capacity. When the temperature is 0-10 degrees Celsius, the battery 318 may never get charged or discharged fully and a higher state of charge value may be calculated or may jump from 100% to 80% for example. To address these issues, the smoothing module 330 may be configured to calculate a weighted offset based on a current charge value. The particular smoothing techniques executed by the smoothing module 330 may be varied and numerous and may include additional techniques not discussed herein. These techniques would be obvious to one skilled in the art.

In some embodiments, the gas gauge engine 302 may include a translation module 332. The translation module 332 may be configured to mask the charge value for a better user experience. For example, perhaps the device 300 (e.g., the wireless headphone 104 of FIG. 1) stops charging if the battery level of its charging device (e.g., the charging device 106 of FIG. 1) is at 5%. To the user, it might be annoying to see 5% in the case and the buds not charging. To make the user experience better the charge value of 5% may be presented as 1% by the charging device 106. The translation module 332 may be configured to perform such translation operations. As another example, the translation module 332 may be configured to translate a charge value for an aged battery. The charge value (e.g., raw, converted, post-smoothing, and/or post-translated) may be stored by any suitable component of the gas gauge engine 302 (e.g., the state of charge module 326, the smoothing module 330, the translation module 332) in the data store 310 for later recall (e.g., in case the device 300 is powered off and then back on).

In some embodiments, the charge value of the battery 318 (e.g., as determined by the state of charge module 326, the smoothing module 330, or the translation module 332) may be provided to the operating system 312 for presentation. In some embodiments, the charge value may be presented at an interface provided by the device 300 such as a display, a lighted indicator, or any suitable output device of I/O device(s) 316. In some embodiments, the charge value of the battery 318 may be transmitted to a remote device (e.g., the user device 130 of FIG. 1) for presentation at an output device of the remote device (e.g., a display of the user device 130).

In some embodiments, the gas gauge engine 302 may include a battery health and diagnostic module 334. In some embodiments, the battery health and diagnostic module 334 may be configured to collect historical charging data (e.g., charging data collected over time before a current time) comprising an age of the battery, a number of cycles corresponding to charges of the battery performed, historical electrical current rates, and an average voltage of the battery over a period of time that corresponds to the age of the battery, etc. In some embodiments, the battery health and diagnostic module 334 may be configured to modify the multi-tiered charging scheme stored in data store 310 based on the historical charging data collected. For example, if the age of the battery is determined to exceed a threshold value, the battery health and diagnostic module 334 may be configured to cause the battery 318 to be charged to 95% instead of 100%. Any suitable operation may be performed based on the collected charging data. In some embodiments, these operations may be performed to extend the life of the battery 318. In still further embodiments, the battery health and diagnostic module 334 may be configured to provide the historical charging data to any suitable requestor (e.g., another component of the device 300, a remote device via an application programming interface, etc.).

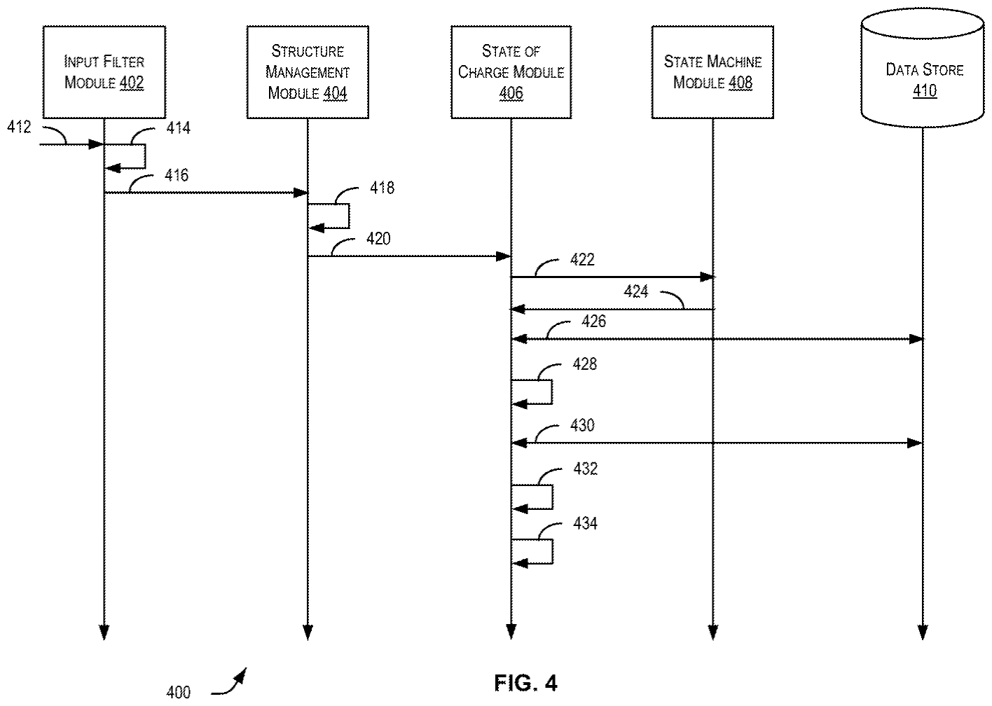

FIG. 4 is a simplified block diagram illustrating an example flow 400 for determining a state of charge of a battery, in accordance with at least one embodiment. The flow 400 may be performed by input filter module 402 (e.g., an example of the input filter module 322 of FIG. 3), structure management module 404 (e.g., an example of the structure management module 324 of FIG. 3), state of charge module 406 (e.g., an example of the state of charge module 326 of FIG. 3, state machine module 408 (e.g., an example of the state machine module 328 of FIG. 3), and data store 410 (e.g., an example of data store 310 of FIG. 3).

The flow may begin at 412 where the input filter module 402 may receive values for voltage, electrical current, and temperature of a battery of the device (e.g., from the power management module 320 of FIG. 3). In some embodiments, the temperature may be initially captured by a sensor of the device on which the modules 402-410 operate (e.g., device 300 of FIG. 3, wireless headphone 104 of FIG. 1, charging device 106 of FIG. 1, etc.).

At 414, the input filter module 402 may perform any suitable filtering operations on the voltage, electrical current, and/or temperature values. For example, the input filter module 402 may perform one or more out of bounds checks to any suitable combination of the voltage, temperature, and/or electrical current values.

At 416, after performing such filtering operations, the input filter module 402 may provide the voltage, electrical current, and temperature values to the structure management module 404.

At 418, the structure management module 404 may obtain a data structure for storing the received values. In some embodiments, the data structure is generated or a previously generated data structure may be retrieved (e.g., from the data store 410). The voltage, electrical current, and temperature values may be stored within the data structure.

At 420, the structure management module 404 may provide the data structure storing the voltage, electrical current, and temperature values to the state of charge module 406.

At 422, the state of charge module 406 may request identification of a charging state from the state machine module 408. At 424, the state machine module 408 may return a state indicating a charging state of the device.

At 426, upon determining that the state received from the state machine module 408 indicates a charging state, the state of charge module 406 may be configured to obtain a table from the data store 410 for determining a charging tier and a current electrical current rate to be applied to the battery. An example of the table obtained at 426 is depicted in FIG. 5.

FIG. 5 is a schematic diagram illustrating an example table 500 associated with a charging scheme that may be utilized to identify an electric current rate to be applied to a battery during a charging state, in accordance with at least one embodiment. As depicted in FIG. 5, a voltage and temperature may be utilized to identify a charge rate (in mA units or another suitable unit) with which the battery is to be charged. As depicted, if voltages of less than or equal to 3.9 V (for this particular battery) indicate a first charging tier, voltages greater than 3.9 and less than or equal to 4.0 V (for this particular batter) indicate a second charging tier, and voltages greater than 4.0 and less than or equal to 4.2 V (for this particular batter) indicate a third charging tier. The specific voltage ranges may vary depending on the type of battery being charged. That is a table for a particular type of battery may be specific to that battery type.

The table 500 may include any suitable number of columns corresponding to any suitable number of charging tiers of a multi-tiered charging scheme. The table 500 may include any suitable number of temperature ranges. In some embodiments, there may be five temperature ranges. The specific temperature ranges may be those depicted in FIG. 5, or the specific temperature ranges may differ from those depicted in FIG. 5.

Returning to FIG. 4, a charging tier and an electrical current rate to be applied to the battery may be determined at 428 (e.g., by the state of charge module 406). The charging tier and the electrical charge rate may correspond to the temperature and voltage provided at 420. By way of example, the temperature and voltage may be utilized with the table 500 of FIG. 5 to identify an electrical current rate. As depicted in FIG. 5, the column of the identified electrical current rate may correspond to a particular charging tier of a multi-tiered charging scheme (e.g., a first charging tier, a second charging tier, a third charging tier, etc.). Although not depicted in FIG. 5, the state of charge module 406 may provide instructions to the power management module 320 of FIG. 3 to cause the power management module 320 to being charging the battery at the electrical current rate identified. In some embodiments, the state of charge module 406 may cause the charging tier and/or the electrical current rate identified to be stored in the data structure (e.g., by storing those values directly, or by providing those values to the structure management module 404 for updating the data structure).

At 430, the state of charge module 406 may obtain a table for identifying a state of charge of the battery. In some embodiments, the state of charge module 406 may utilize the charging tier identified at 428, the voltage and/or the electrical current provided at 420 to identify whether the battery is being charged in a constant voltage phase or a constant electrical current phase. Depending on the type of phase currently being utilized, the state of charge module 406 may obtain a corresponding table from the data store 410.

FIG. 6 is a schematic diagram illustrating example tables associated with constant voltage phases of a multi-tiered charging scheme, in accordance with at least one embodiment. By way of example, table 602 may correspond with a first charging tier. Table 604 may correspond to a second charging tier. Table 606 may correspond to a third charging tier. Although a certain number of tables are depicted, it should be appreciated that any suitable mapping and/or container may be utilized in a similar manner as described herein. Each row of the tables 602-606 may be considered a separate table and may be stored in a different container than the other rows. Each of the tables 602-606 (or rows of tables 602-606) may be a multi-dimensional table with inputs corresponding to temperature and electrical current (e.g., the temperature and the electrical current received at 420 of FIG. 4).

The value returned from each table given the inputs may be a charge value expressing an amount of charge of the battery. In some embodiments, the charge value may be a raw value expressed in millivolts or another suitable unit. In some embodiments, the charge value may be expressed in a percentage value indicating a charge percentage of a total charge capacity of the battery (e.g., 0.30 indicating the battery is charged to 30% of total capacity).

In some embodiments, the first row of each table may correspond to a particular temperature range (e.g., greater than or equal to 0 degrees Celsius to less than 5 degrees Celsius). The exemplary temperature ranges of FIG. 6 may further include greater than or equal to 5 degrees Celsius to less than 10 degrees Celsius, greater than or equal to 10 degrees Celsius to less than 22 degrees Celsius, greater than or equal to 22 degrees Celsius to less than 38 degrees Celsius, and greater than 38 degrees Celsius. However, any suitable temperature range and/or number of temperature ranges may be utilized.

A charging tier and temperature value may be utilized to identify a particular table (e.g., a table corresponding to a row of table 602, table 602 including five tables corresponding to the first charging tier of a multi-tiered charging scheme). Once obtained, the electrical current (e.g., the electrical current provided to the gas gauge engine 102 or the electrical current as filtered by the input filter module 322 of FIG. 3) may be provided to the table obtained to retrieve a value corresponding to the charge value of the battery. If the electrical current falls between values corresponding to the columns of the table obtained, a linear interpolation technique may be utilized to estimate the charge value. By way of example for a temperature of 22 degrees Celsius in the first charging tier (e.g., corresponding to the 4^{th} row of table 602). A charge value when the electrical current is at 137 milliamps may be identified by first determining the charge value at column 1 corresponding to 141 milliamps, and a second charge value corresponding to column 2 corresponding to 133 milliamps. The difference in charge values may be divided by the difference between electrical currents (e.g., between 141 and 133 milliamps). The resultant number may be multiplied by four (the difference between 141 milliamps and the electrical current rate input of 137 milliamps) to identify the charge value corresponding to 137 milliamps.

FIG. 7 is a schematic diagram illustrating example tables 700 associated with constant electrical current phases of a multi-tiered charging scheme, in accordance with at least one embodiment. By way of example, table 702 may correspond with a first charging tier. Table 704 may correspond to a second charging tier. Table 706 may correspond to a third charging tier. Although tables are depicted in FIG. 7, it should be appreciated that any suitable mapping and/or container may be utilized in a similar manner as described herein. In some embodiments, each row of the tables 702-706 may be considered a separate table and may be stored in a different container than the other rows. Each of the tables 702-706 (or rows of tables 702-706) may be a multi-dimensional table with inputs corresponding to temperature and voltage.

The value returned from each table given the inputs may be a charge value expressing an amount of charge of the battery. In some embodiments, the charge value may be a raw value expressed in millivolts or another suitable unit. In some embodiments, the charge value may be expressed in a percentage value indicating a charge percentage of a total charge capacity of the battery (e.g., 0.40 indicating the battery is charged to 40% of total capacity).

In some embodiments, each row of the tables 702-706 may correspond to a particular temperature range (e.g., greater than or equal to 0 degrees Celsius to less than 5 degrees Celsius). The exemplary temperature ranges of FIG. 7 may further include greater than or equal to 5 degrees Celsius to less than 10 degrees Celsius, greater than or equal to 10 degrees Celsius to less than 22 degrees Celsius, greater than or equal to 22 degrees Celsius to less than 38 degrees Celsius, and greater than 38 degrees Celsius. However, any suitable temperature range and/or number of temperature ranges may be utilized.

A charging tier and temperature value may be utilized to identify a particular table (e.g., a table corresponding to a row of table 702, table 702 including five tables corresponding to the first charging tier of a multi-tiered charging scheme). Once obtained, the voltage (e.g., in millivolts) may be provided to the table obtained to retrieve a value corresponding to the charge value of the battery. If the voltage falls between values corresponding to the columns of the table obtained, a linear interpolation technique may be utilized to estimate the charge value. By way of example for a temperature of 22 degrees Celsius in the first charging tier (e.g., corresponding to the 4^{th} row of table 702). An charge value corresponding to a voltage of 3600 millivolts may be identified by first determining the charge value at column 1 corresponding to 3460 millivolts, and a second charge value corresponding to column 2 corresponding to 3735 millivolts. The difference in charge values may be divided by the difference between 3460 and 3735 millivolts. The resultant number may be multiplied a number corresponding to the difference between 3460 millivolts and 3600 millivolts to identify the charge value corresponding to 3600 millivolts.

Returning to FIG. 4, at 430, the state of charge module 406 may obtain a table from one of the tables depicted in FIG. 6 when the battery is being charged in a constant voltage phase or one of the tables depicted in FIG. 7 when the battery is being charged in a constant electrical current phase.

At 432, the state of charge module 406 may be configured to provide the temperature and either the electrical current rate (when in a constant voltage phase) or the voltage (when in a constant electrical current phase) to identify the charge value of the battery.

At 434, the state of charge module 406 may be configured to perform any suitable operations utilizing the charge value. By way of example, the charge value may be stored at data store 410. As another example, the charge value may be converted in any suitable matter by the state of charge module 406 to obtain a format for presentation. In some embodiments, the charge value may be provided by the state of charge module 406 to the smoothing module 330 and/or the translation module 332 of FIG. 3. As yet another example, the charge value may be provided (e.g., by the state of charge module 406 or any suitable module of the gas gauge engine 302 of FIG. 3) to the operating system of the device (e.g., operating system 312 of FIG. 3). In some embodiments, the charge value may be transmitted to a remote device (e.g., the user device 130 of FIG. 3) for presentation.

It should be appreciated that the operations of flow 400 may be repeated any suitable number of times at any suitable frequency. In some embodiments, the gas gauge engine 302 of FIG. 3, including the components 304 (e.g., at least the modules depicted in FIG. 4) may monitor the temperature, voltage, an electrical current with respect to the battery over time (e.g., every few seconds, milliseconds, etc.). As the temperature, voltage, and electrical current change, the gas gauge engine 302 may instruct the power management module 320 according to the electrical current rate identified from the temperature and voltage. The gas gauge engine 302 may further utilize the voltage and/or electrical current to lookup the charge value from an appropriate mapping as described above.

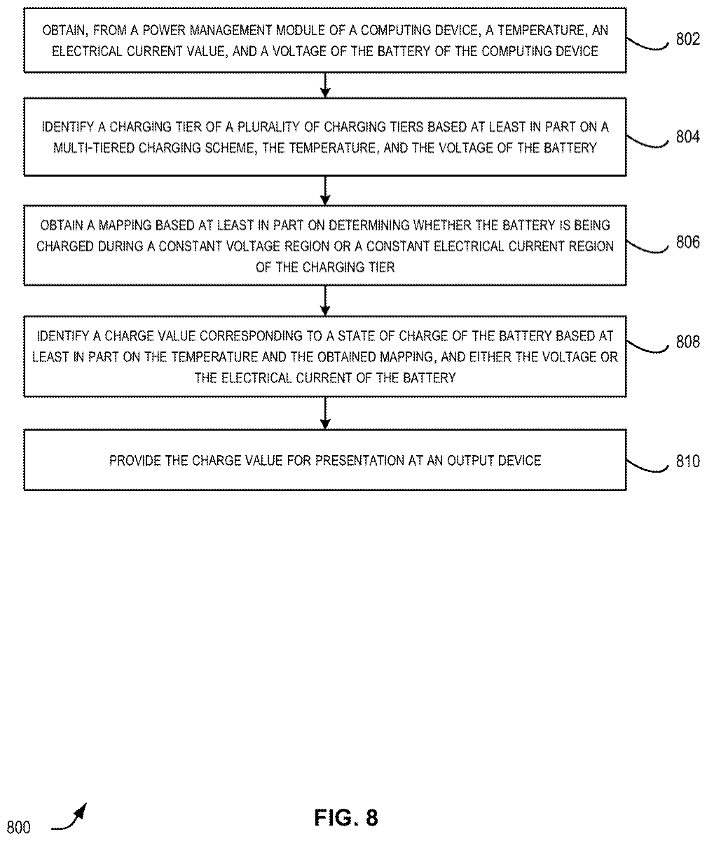

FIG. 8 is a flow diagram to illustrate an example method 800 for determining a state of charge of a battery, in accordance with at least one embodiment. Method 800 may be performed by a gas gauge engine (e.g., the gas gauge engines 102 and 302 of FIGS. 1 and 3, respectively) having at least one processor and at least one memory storing computer-readable instructions. Execution of the computer-readable instructions by the at least one processor may configure the gas gauge engine to execute the operations of method 800. It should be appreciated that the operations of method 800 may be performed in any suitable order. Additional operations may be included, or at least one of the operations of method 800 may be excluded in some embodiments.

At block 802, a temperature, an electrical current value, and a voltage of a battery of a computing device may be obtained (e.g., by the gas gauge engine from the power management module 320 of FIG. 3). In some embodiments, the temperature, voltage, and electrical current rate being utilized to charge the battery may be obtained.

At 804, a charging tier of a plurality of charging tiers may be identified (e.g., by the state of charge module 326 of FIG. 3). In some embodiments, the charging tier may be selected from the plurality of charging tiers based at least in part on a multi-tiered charging scheme, the temperature, and the voltage of the battery. In still further embodiments, the charging tier may be selected from the plurality of charging tiers based at least in part on a multi-tiered charging scheme, the temperature, and the voltage of the battery as well as the electrical current rate being utilized to charge the battery.

At 806, a mapping may be obtained (e.g., by the state of charge module 326 from the data store 310 of FIG. 3) based at least in part on whether the battery is being charged during a constant voltage phase or a constant electrical current phase of the charging tier. The mapping, in this example, may correspond to a row of a table depicted in FIG. 6 when the battery is being charged during a constant voltage phase or a row of a table depicted in FIG. 7 when the battery is being charged during a constant electrical current phase.

At 808, a charge value corresponding to a state of charge of the battery may be identified (e.g., by the state of charge module 326) based at least in part on the temperature and the obtained mapping, and either the voltage or the electrical current value of the battery.

At 810, the charge value may be provided (e.g., by the state of charge module 326 or any suitable module of the gas gauge engine 302 of FIG. 3) for presentation. In some embodiments, presentation may include presenting a visual and/or audible indication of the state of charge (e.g., the charge value such as 30% charged) at the device and/or at a remote device different from the device which operates from the battery being charged.

Illustrative methods, computer-readable medium, and systems for providing various techniques for pairing proximate devices are described above. Some or all of these systems, media, and methods may, but need not, be implemented at least partially by architectures and flows such as those shown at least in FIGS. 1-8 above. It should be understood that any of the above techniques can be used within any type of application operating at an accessory device or a host device. For purposes of explanation, specific configurations and details are set forth in order to provide a thorough understanding of the examples. However, it should also be apparent to one skilled in the art that the examples may be practiced without the specific details. Furthermore, well-known features were sometimes omitted or simplified in order not to obscure the example being described.

The various embodiments further can be implemented in a wide variety of operating environments, which in some cases can include one or more user computers, accessory devices and/or host devices which can be used to operate any of a number of applications. Accessory devices and/or host devices can include any of a number of general purpose personal computers, such as desktop or laptop computers running a standard operating system, as well as cellular, wireless and handheld devices running mobile software and capable of supporting a number of networking and messaging protocols. Such a system also can include a number of workstations running any of a variety of commercially-available operating systems and other known applications for purposes such as development and database management. These devices also can include other electronic devices, such as dummy terminals, thin-clients, gaming systems and other devices capable of communicating via a network.

Most embodiments utilize at least one network that would be familiar to those skilled in the art for supporting communications using any of a variety of commercially-available protocols, such as TCP/IP, OSI, FTP, UPnP, NFS, CIFS, and AppleTalk. The network can be, for example, a local area network, a wide-area network, a virtual private network, the Internet, an intranet, an extranet, a public switched telephone network, an infrared network, a wireless network, and any combination thereof.

The environment can include a variety of data stores and other memory and storage media as discussed above. These can reside in a variety of locations, such as on a storage medium local to (and/or resident in) one or more of the computers or remote from any or all of the computers across the network. In a particular set of embodiments, the information may reside in a storage-area network (SAN) familiar to those skilled in the art. Similarly, any necessary files for performing the functions attributed to the computers, servers or other network devices may be stored locally and/or remotely, as appropriate. Where a system includes computerized devices, each such device can include hardware elements that may be electrically coupled via a bus, the elements including, for example, at least one central processing unit (CPU), at least one input device (e.g., a mouse, keyboard, controller, touch screen or keypad), and at least one output device (e.g., a display device, printer or speaker). Such a system may also include one or more storage devices, such as disk drives, optical storage devices, and solid-state storage devices such as RAM or ROM, as well as removable media devices, memory cards, flash cards, etc.

Such devices also can include a computer-readable storage media reader, a communications device (e.g., a modem, a network card (wireless or wired), an infrared communication device, etc.), and working memory as described above. The computer-readable storage media reader can be connected with, or configured to receive, a non-transitory computerreadable storage medium, representing remote, local, fixed, and/or removable storage devices as well as storage media for temporarily and/or more permanently containing, storing, transmitting, and retrieving computer-readable information. The system and various devices also typically will include a number of software applications, modules, services or other elements located within at least one working memory device, including an operating system and application programs, such as a client application or browser. It should be appreciated that alternate embodiments may have numerous variations from that described above. For example, customized hardware might also be used and/or particular elements might be implemented in hardware, software (including portable software, such as applets) or both. Further, connection to other computing devices such as network input/output devices may be employed.

Non-transitory storage media and computer-readable storage media for containing code, or portions of code, can include any appropriate media known or used in the art (except for transitory media like carrier waves or the like) such as, but not limited to, volatile and non-volatile, removable and non-removable media implemented in any method or technology for storage of information such as computer-readable instructions, data structures, program modules or other data, including RAM, ROM, Electrically Erasable Programmable Read-Only Memory (EEPROM), flash memory or other memory technology, CD-ROM, DVD or other optical storage, magnetic cassettes, magnetic tape, magnetic disk storage or other magnetic storage devices or any other medium which can be used to store the desired information and which can be accessed by a system device. Based on the disclosure and teachings provided herein, a person of ordinary skill in the art will appreciate other ways and/or methods to implement the various embodiments. However, as noted above, computer-readable storage media does not include transitory media such as carrier waves or the like.

As described above, one aspect of the present technology collects historical charging data. The present disclosure contemplates that in some instances, this gathered data may include personal information data that uniquely identifies charging behaviors. The present disclosure recognizes that the use of such data, in the present technology, can be used to the benefit of users. For example, the device information can be used to adjust a multi-tiered charging scheme utilized to charge the user's device.

The present disclosure contemplates that the entities responsible for the collection, analysis, disclosure, transfer, storage, or other use of such data (e.g., charging data) will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. Hence different privacy practices should be maintained for different personal data types in each country.

Despite the foregoing, the present disclosure also contemplates embodiments in which users selectively block the use of, or access to, charging data. That is, the present disclosure contemplates that hardware and/or software elements can be provided to prevent or block access to such charging data. For example, in some embodiments, the user may opt out of any data collection procedures discussed herein. In addition to providing “opt in” and “opt out” options, the present disclosure contemplates providing notifications relating to the access or use of charging data.

Moreover, it is the intent of the present disclosure that data should be managed and handled in a way to minimize risks of unintentional or unauthorized access or use. Risk can be minimized by limiting the collection of data and deleting data once it is no longer needed. In addition, and when applicable, data de-identification can be used to protect a user's privacy. De-identification may be facilitated, when appropriate, by removing specific identifiers, controlling the amount or specificity of data stored, controlling how data is stored, and/or other methods.

Therefore, although the present disclosure broadly covers use of charging data to implement one or more various disclosed embodiments, the present disclosure also contemplates that the various embodiments can also be implemented without the need for accessing such personal information data.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims.

The use of the terms “a,” “an,” and “the,” and similar referents in the context of describing the disclosed embodiments (especially in the context of the following claims), are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. The term “connected” is to be construed as partly or wholly contained within, attached to, or joined together, even if there is something intervening. The phrase “based on” should be understood to be open-ended, and not limiting in any way, and is intended to be interpreted or otherwise be read as “based at least in part on,” where appropriate. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate embodiments of the disclosure and does not pose a limitation on the scope of the disclosure unless otherwise claimed. No language in the specification should be construed as indicating any non-claimed element as essential to the practice of the disclosure.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present. Additionally, conjunctive language such as the phrase “at least one of X, Y, and Z,” unless specifically stated otherwise, should also be understood to mean X, Y, Z, or any combination thereof, including “X, Y, and/or Z.”

As described above, one aspect of the present technology provides device information via advertisement messages. The present disclosure contemplates that in some instances, this gathered data may include personal information data that uniquely identifies or can be used to contact or locate a specific person utilizing the device information. The present disclosure recognizes that the use of such personal information data, in the present technology, can be used to the benefit of users. For example, the device information can be used to provide an efficient and user-friendly way to pair accessory and host devices.

The present disclosure contemplates that the entities responsible for the collection, analysis, disclosure, transfer, storage, or other use of such personal information data (e.g., device information) will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in some embodiments, the user may opt out of performing the pairing procedures and/or data connection procedures discussed herein. In addition to providing “opt in” and “opt out” options, the present disclosure contemplates providing notifications relating to the access or use of personal information. In some embodiments, the present disclosure contemplates providing a notification that a device has been paired to the user's device. This may notify the user of potentially fraudulent pairing by unauthorized users.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, data de-identification can be used to protect a user's privacy. De-identification may be facilitated, when appropriate, by removing specific identifiers, controlling the amount or specificity of data stored, controlling how data is stored, and/or other methods.

Therefore, although the present disclosure broadly covers use of personal information data to implement one or more various disclosed embodiments, the present disclosure also contemplates that the various embodiments can also be implemented without the need for accessing such personal information data.

The specification and drawings are, accordingly, to be regarded in an illustrative rather than a restrictive sense. It will, however, be evident that various modifications and changes may be made thereunto without departing from the broader spirit and scope of the disclosure as set forth in the claims.

Other variations are within the spirit of the present disclosure. Thus, while the disclosed techniques are susceptible to various modifications and alternative constructions, certain illustrated embodiments thereof are shown in the drawings and have been described above in detail. It should be understood, however, that there is no intention to limit the disclosure to the specific form or forms disclosed, but on the contrary, the intention is to cover all modifications, alternative constructions and equivalents falling within the spirit and scope of the disclosure, as defined in the appended claims.

Illustrative embodiments of this disclosure are described herein, including the best mode known to the inventors for carrying out the disclosure. Variations of those illustrative embodiments may become apparent to those of ordinary skill in the art upon reading the foregoing description. The inventors expect skilled artisans to employ such variations as appropriate, and the inventors intend for the disclosure to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

All references, including publications, patent applications, and patents, cited herein are hereby incorporated by reference to the same extent as if each reference were individually and specifically indicated to be incorporated by reference and were set forth in its entirety herein.

What is claimed is:

1. A computer-implemented method, comprising:
obtaining, by a computing device from a power management module of the computing device, a temperature, an electrical current value, and a voltage of a battery of the computing device;
identifying a charging tier of a plurality of charging tiers based at least in part on a multi-tiered charging scheme, the temperature, and the voltage of the battery;
obtaining a mapping based at least in part on determining whether the battery is being charged during a constant voltage phase or a constant electrical current phase of the charging tier;
identifying a charge value corresponding to a state of charge of the battery based at least in part on the temperature and the obtained mapping, and either the voltage of the battery or the electrical current value; and
providing the charge value for presentation.

2. The computer-implemented method of claim 1, wherein the power management module is hardware of the computing device that comprises an integrated circuit.

3. The computer-implemented method of claim 1, wherein the mapping is one of a plurality of mappings comprising a first set of mappings to be utilized during constant voltage phases of each charging tier of the plurality of charging tiers, the plurality of mappings further comprising a second set of mappings to be utilized during constant electrical current phases of each charging tier of the plurality of charging tiers.

4. The computer-implemented method of claim 1, wherein the mapping is one of a plurality of mappings, each mapping of the plurality of mappings corresponding to a temperature range and a particular charging tier of the plurality of charging tiers.

5. The computer-implemented method of claim 4, wherein the plurality of mappings are associated with a battery type of the battery being charged.

6. The computer-implemented method of claim 1, further comprising:
identifying an electrical current rate to be applied to the battery based at least in part on the temperature, the voltage of the battery, and the identified charging tier; and
instructing the power management module of the computing device to apply electrical current at the electrical current rate based at least in part on writing a charging value corresponding to the electrical current rate to a register of the power management module.

7. The computer-implemented method of claim 6, wherein the electrical current rate decreases with each successive tier according to the multi-tiered charging scheme.

8. The computer-implemented method of claim 6, wherein the multi-tiered charging scheme specifies that the electrical current rate applied to the battery differs between at least two charging tiers.

9. A computing device, comprising:
a battery;
a memory comprising computer-executable instructions; and
one or more processors in communication with the memory and configured to access the memory and execute the computer-executable instructions to perform operations comprising:
obtaining a temperature, an electrical current value, and a voltage of the battery of the computing device;
identifying a charging tier of a plurality of charging tiers based at least in part on a multi-tiered charging scheme, the temperature, and the voltage of the battery;
obtaining a mapping based at least in part on determining whether the battery is being charged during a constant voltage phase or a constant electrical current phase of the charging tier;
identifying a charge value corresponding to a state of charge of the battery based at least in part on the temperature and the obtained mapping, and either the voltage of the battery or the electrical current value; and
providing the charge value for presentation.

10. The computing device of claim 9, wherein the temperature is obtained from a thermal sensor of the computing device.

11. The computing device of claim 9, wherein the temperature, the electrical current value, and the voltage of the battery is obtained from a power management module of the computing device, and obtaining the temperature, the electrical current value, and the voltage of the battery is performed by a software module of the computing device.

12. The computing device of claim 11, wherein the software module is firmware of the computing device.

13. The computing device of claim 9, further comprising modifying the charge value based at least in part on one or more smoothing techniques.

14. One or more computer-readable storage media comprising computer-executable instructions that, when executed by one or more processors of a computing device, the computing device to perform operations comprising:
obtaining a temperature, an electrical current value, and a voltage of a battery of a computing device;
identifying a charging tier of a plurality of charging tiers based at least in part on a multi-tiered charging scheme, the temperature, and the voltage of the battery;
obtaining a mapping based at least in part on determining whether the battery is being charged during a constant voltage phase or a constant electrical current phase of the charging tier;
identifying a charge value corresponding to a state of charge of the battery based at least in part on the temperature and the obtained mapping, and either the voltage of the battery or the electrical current value; and
providing the charge value for presentation.

15. The one or more computer-readable storage media of claim 14, wherein the voltage is utilized to identify the charge value corresponding to the state of charge of the battery when the battery is being charged during a constant electrical current phase of the charging tier, and wherein the electrical current value is utilized to identify the charge value corresponding to the state of charge of the battery when the battery is being charged during the constant voltage phase of the charging tier.

16. The one or more computer-readable storage media of claim 14, wherein the mapping is stored non-volatile memory of the one or more computer-readable storage media.

17. The one or more computer-readable storage media of claim 14, wherein the operations further comprise collecting historical charging data including an age of the battery, a number of cycles corresponding to charges of the battery performed, historical electrical current rates, and an average voltage of the battery over a period of time that corresponds to the age of the battery.

18. The one or more computer-readable storage media of claim 17, wherein the operations further comprise adjusting the multi-tier charging scheme based at least in part on the historical charging data collected over time.

19. The one or more computer-readable storage media of claim 14, wherein the operations further comprise filtering the temperature and voltage utilizing an out of bounds check to remove outlier temperatures and voltages.

20. The one or more computer-readable storage media of claim 14, wherein identifying the charge value corresponding to the state of charge of the battery utilizes linear interpolation.
